(19) United States
(12) Patent Application Publication
(10) Pub. No.: US 2020/0324371 A1
(43) Pub. Date: Oct. 15, 2020

(54) Process Method for Improving Welding Seam Quality of Laser Lap Welding

(71) Applicant: CRRC QINGDAO SIFANG CO., LTD., Qingdao (CN)

(72) Inventors: Xiaohui HAN, Qingdao (CN); Ruirong ZHAO, Qingdao (CN); Yonggang LIU, Qingdao (CN); Aihua MA, Qingdao (CN)

(21) Appl. No.: 16/305,564

(22) PCT Filed: Oct. 26, 2017
(86) PCT No.: PCT/CN2017/107754

§ 371 Date: Nov. 29, 2018

(30) Foreign Application Priority Data
Nov. 18, 2016 (CN) 201611015685.2

(51) Int. Cl. B23K 26/244; B23K 26/03; G06F 30/20

(52) U.S. Cl. CPC B23K 26/244; B23K 2101/006; G06F 30/20; B23K 26/03

(57) ABSTRACT

A process method for improving the welding seam quality of laser lap welding, including: S100: performing laser welding simulation on a workpiece and determining heat source model parameters of the laser welding simulation; S200: performing, according to the heat source model parameters, welding simulation on the workpiece at different incident angles, so as to acquire first welding seam parameters corresponding to the different incident angles; and S300: when the first welding seam parameters fall within a preset range, determining the incident angles corresponding to the first welding seam parameters as actual laser incident angles. The method can improve the problem of unstable welding seam quality of laser lap welding.

### TECHNICAL FIELD

Embodiments of the present disclosure relate to a technical field of laser lap welding, and in particular to a process method for improving a welding seam quality of laser lap welding.

### BACKGROUND

At present, compared with a vehicle body made of ordinary carbon steel and aluminum alloy, a stainless steel vehicle body has the characteristics of low comprehensive cost, long operating life, high safety and the like, has become an important material for rail traffic, and has been widely used. At present, welding of the stainless steel vehicle body has been transitioned from spot welding to laser welding to achieve the aims of good appearance, high strength and good sealing performance.

In the conventional art, when laser lap welding is performed using a stainless steel sheet, in order to ensure a certain tensile strength, it is necessary to ensure a certain weld melt width. Furthermore, there are certain requirements for the continuity, stability and back state of the weld penetration of a workpiece. There are many factors affecting the weld melt width and the weld penetration during laser welding. An incident angle of laser is an important factor affecting the shape and quality of a lap welded joint.

The method for determining an incident angle of laser is not mentioned in the conventional art, and therefore, the quality stability of the workpiece after welding cannot be guaranteed during the actual operation. Therefore, there is a need in the conventional art for a method of determining an incident angle of laser to ensure the welding seam quality of lap welding.

### SUMMARY

The present disclosure provides a process method for improving a welding seam quality of laser lap welding, intended to solve the problem in the conventional art that an incident angle of laser cannot be determined.

The present disclosure provides a process method for improving a welding seam quality of laser lap welding. The method includes the steps as follows. In S100, laser welding simulation is performed on a workpiece, and a heat source model parameter of the laser welding simulation is determined. In S200, welding simulations are performed on the workpiece at different incident angles according to the heat source model parameter, so as to acquire first welding seam parameters corresponding to the different incident angles. In S300, when at least one first welding seam parameter of the first welding seam parameters falls within a preset range, a respective incident angle corresponding to the at least one first welding seam parameter is determined as an actual laser incident angle.

In some embodiments, S100 includes the sub-steps as follows. In S101, the workpiece is actually welded according to a preset incident angle and acquiring an actual welding seam parameter of the workpiece. In S103, the heat source model parameter of the laser welding simulation is adjusted according to the actual welding seam parameter of the workpiece.

In some embodiments, before S103 is performed, S100 also includes the sub-step as follows. In S102, a welding simulation is performed on the workpiece according to the preset incident angle, so as to acquire a second welding seam parameter corresponding to the preset incident angle, wherein after S102 is performed, in S103, the heat source model parameter of the laser welding simulation is adjusted according to the actual welding seam parameter of the workpiece and the second welding seam parameter.

In some embodiments, a first welding seam parameter includes a penetration dimension of a welding seam and a melt width dimension of a welding seam.

In some embodiments, the preset range includes a first preset range, and S300 includes the sub-step as follows. In S301, when at least one penetration dimension falls within the first preset range, a respective incident angle corresponding to the at least one penetration dimension is determined as the actual laser incident angle.

In some embodiments, the preset range includes a first preset range and a second preset range, and when a plurality of penetration dimensions corresponding to a plurality of incident angles fall within the first preset range, S300 also includes the sub-steps as follows. In S302, multiple incident angles meeting the first preset range are determined according to the first preset range. In S303, a plurality of melt width dimensions corresponding to the multiple incident angles meeting the first preset range are acquired according to the multiple incident angles meeting the first preset range. In S304, when a melt width dimension of the plurality of melt width dimensions corresponding to the multiple incident angles meeting the first preset range meets the second preset range, an incident angle corresponding to the melt width dimension is determined as the actual laser incident angle.

In some embodiments, the heat source model parameter includes a heat source power, a welding speed, and a heat source radius.

In some embodiments, after S300 is performed, the process method also includes the step as follows. In S400, the workpiece is actually welded according to the actual laser incident angle.

By applying the technical solution of the present disclosure, laser welding simulation is performed on a workpiece, and a heat source model parameter of the laser welding simulation is determined; welding simulations are performed on the workpiece at different incident angles according to the heat source model parameter, so as to obtain first welding seam parameters corresponding to the different incident angles; and when at least one first welding seam parameter of the first welding seam parameters falls within a preset range, a respective incident angle corresponding to the at least one first welding seam parameter is determined as an actual laser incident angle. By means of the method, before a workpiece is actually welded, welding simulation tests may be performed on the workpiece first, and an actual laser incident angle may be determined according to a measured first welding seam parameter. Thus, whilst a laser welding angle of the workpiece during actual welding is determined, the welding quality of laser lap welding is improved, and the stability of the laser lap welding is improved.

### BRIEF DESCRIPTION OF THE DRAWINGS

The accompanying drawings, which constitute a part of this application, are used to provide a further understanding of the present disclosure, and the exemplary embodiments of the present disclosure and the description thereof are used to explain the present disclosure, but do not constitute improper limitations to the present disclosure. In the drawings:

FIG. 1 illustrates a flowchart of a process method for improving the welding seam quality of laser lap welding according to an embodiment of the present disclosure; and

FIG. 2 illustrates a structural schematic diagram of workpiece welding according to an embodiment of the present disclosure.

### DETAILED DESCRIPTION OF THE EMBODIMENTS

The technical solutions in the embodiments of the present disclosure will be clearly and completely described hereinbelow with the drawings in the embodiments of the present disclosure. It is apparent that the described embodiments are only part of the embodiments of the present disclosure, not all of the embodiments. The following description of at least one exemplary embodiment is only illustrative actually, and is not used as any limitation for the present disclosure and the application or use thereof. On the basis of the embodiments of the present disclosure, all other embodiments obtained on the premise of no creative work of those of ordinary skill in the art fall within the scope of protection of the present disclosure.

It is to be noted that terms used herein only aim to describe specific implementation manners, and are not intended to limit exemplar implementations of this application. Unless otherwise directed by the context, singular forms of terms used herein are intended to include plural forms. Besides, it will be also appreciated that when terms “contain” and/or “include” are used in the description, it is indicated that features, steps, operations, devices, assemblies and/or a combination thereof exist.

Unless otherwise specified, relative arrangements of components and steps elaborated in these embodiments, numeric expressions and numeric values do not limit the scope of the present disclosure. Furthermore, it should be understood that for ease of descriptions, the size of each part shown in the drawings is not drawn in accordance with an actual proportional relation. Technologies, methods and devices known by those skilled in the related art may not be discussed in detail. However, where appropriate, the technologies, the methods and the devices shall be regarded as part of the authorized description. In all examples shown and discussed herein, any specific values shall be interpreted as only exemplar values instead of limited values. As a result, other examples of the exemplar embodiments may have different values. It is to be noted that similar marks and letters represent similar items in the following drawings. As a result, once a certain item is defined in one drawing, it is unnecessary to further discus the certain item in the subsequent drawings.

In the descriptions of the present disclosure, it will be appreciated that locative or positional relations indicated by “front, back, up, down, left, and right”, “horizontal, vertical, perpendicular, and horizontal”, “top and bottom” and other terms are locative or positional relations shown on the basis of the drawings, which are only intended to make it convenient to describe the present disclosure and to simplify the descriptions without indicating or impliedly indicating that the referring device or element must have a specific location and must be constructed and operated with the specific location, and accordingly it cannot be understood as limitations to the present disclosure. The nouns of locality “inner and outer” refer to the inner and outer contours of each component.

For ease of description, spatial relative terms such as “over”, “above”, “on an upper surface” and “upper” may be used herein for describing a spatial position relation between a device or feature and other devices or features shown in the drawings. It will be appreciated that the spatial relative terms aim to contain different orientations in usage or operation besides the orientations of the devices described in the drawings. For example, if the devices in the drawings are inverted, devices described as “above other devices or structures” or “over other devices or structures” will be located as “below other devices or structures” or “under other devices or structures”. Thus, an exemplar term “above” may include two orientations namely “above” and “below”. The device may be located in other different modes (rotated by 90 degrees or located in other orientations), and spatial relative descriptions used herein are correspondingly explained.

In addition, it is to be noted that terms “first”, “second” and the like are used to limit parts, and are only intended to distinguish corresponding parts. If there are no otherwise statements, the above terms do not have special meanings, such that they cannot be understood as limits to the scope of protection of the present disclosure.

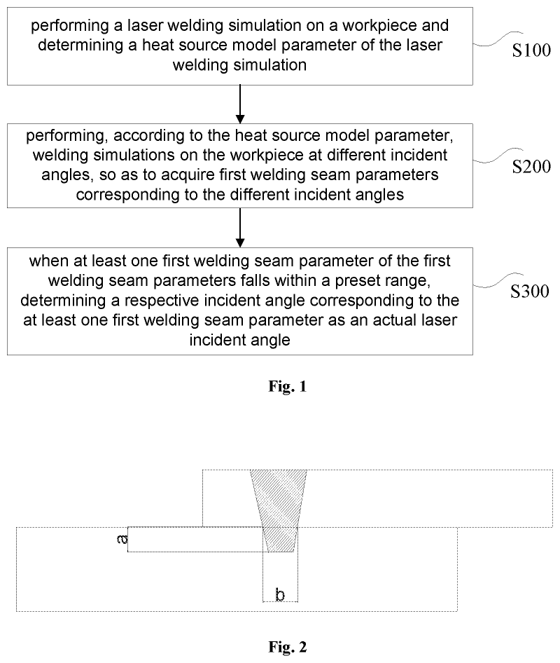

As shown in FIG. 1, the embodiment of the present disclosure provides a process method for improving a welding seam quality of laser lap welding. Specifically, the method includes the steps as follows.

In S100, a laser welding simulation is performed on a workpiece, and a heat source model parameter of the laser welding simulation is determined.

Specifically, before simulated welding is performed on the workpiece, a heat source model parameter value of the simulated welding is debugged first to match a simulated value with an actual value, thereby improving the simulation accuracy and the reliability of data, and providing a data support for subsequent actual welding.

In S200, welding simulations are performed on the workpiece at different incident angles according to the heat source model parameter, so as to acquire first welding seam parameters corresponding to the different incident angles.

After the heat source model parameter is determined, welding simulations are performed on the workpiece, the simulation tests may be performed for multiple times, and the laser incident angle needs to be adjusted for each simulation, so as to acquire first welding seam parameters of the workpiece corresponding to different incident angles.

In S300, when at least one first welding seam parameter of the first welding seam parameters falls within a preset range, a respective incident angle corresponding to the at least one first welding seam parameter is determined as an actual laser incident angle.

After the first welding seam parameters corresponding to the different incident angles are acquired, judgment is performed according to the first welding seam parameters, and when at least one first welding seam parameter of the first welding seam parameters falls within a preset range, a respective incident angle corresponding to the at least one first welding seam parameter may be determined as an actual laser incident angle.

By applying the embodiment of the present disclosure, laser welding simulation is performed on a workpiece, and a heat source model parameter of the laser welding simulation is determined; welding simulations are performed on the workpiece at different incident angles according to the heat source model parameter, so as to obtain first welding seam parameters corresponding to the different incident angles; and when at least one first welding seam parameter of the first welding seam parameters falls within a preset range, a respective incident angle corresponding to the at least one first welding seam parameter is determined as an actual laser incident angle. By means of the method, before a workpiece is actually welded, welding simulation tests may be performed on the workpiece first, and an actual laser incident angle may be determined according to a measured first welding seam parameter. Thus, whilst a laser welding angle of the workpiece during actual welding is determined, the welding quality of laser lap welding is improved, and the stability of the laser lap welding is improved.

Specifically, S100 includes the sub-steps as follows.

In S101, the workpiece is actually welded according to a preset incident angle and acquiring an actual welding seam parameter of the workpiece.

In S103, the heat source model parameter of the laser welding simulation is adjusted according to the actual welding seam parameter of the workpiece.

In the present embodiment, before the simulated welding is performed on the workpiece, the heat source model parameter is debugged first. Specifically, in practice, the workpiece is welded according to a preset incident angle, and the actual welding seam parameter of the workpiece is measured and acquired after welding. Then, in the simulation, the heat source model parameter is first debugged according to the actual welding seam parameter of the workpiece. After the debugging, simulated weldings are performed on the workpiece at multiple incident angles, first welding seam parameters are acquired, and an actual laser incident angle is determined according to the first welding seam parameter values. By debugging the heat source model parameter, the accuracy and reliability of the simulation can be further improved. Herein, the heat source model parameter value includes a heat source power, a welding speed, and a heat source radius.

Specifically, before S103 is performed, S100 also includes S102. In S102, specifically, welding simulation is performed on the workpiece according to the preset incident angle, so as to acquire a second welding seam parameter corresponding to the preset incident angle. After S102 is performed, in S103, the heat source model parameter of the laser welding simulation is adjusted according to the actual welding seam parameter of the workpiece and the second welding seam parameter.

After the actual welding seam parameter of the workpiece is acquired, the heat source model parameter is debugged. Specifically, the welding simulation is performed on the workpiece according to the preset incident angle, a second welding seam parameter corresponding to the preset incident angle is acquired, and the heat source model parameter is debugged by comparing the actual welding seam parameter with the second welding seam parameter. Specifically, the welding seam parameter may include a melt width dimension, a penetration dimension, a welding seam shape, etc. During the debugging, the heat source model parameter value may be determined by comparing and debugging to make the second welding seam parameter satisfy the actual welding seam parameter, and the workpiece is simulated according to the heat source model parameter value.

In the present embodiment, the preset range includes a first preset range, and S300 includes the sub-step as follows.

In S301, when at least one penetration dimension falls within the first preset range, a respective incident angle corresponding to the at least one penetration dimension is determined as the actual laser incident angle.

Herein, the welding seam parameter includes a melt width dimension, a penetration dimension, a welding seam shape, and other parameter values. In the present embodiment, the penetration dimension is selected as the basis for determining the actual laser incident angle. The penetration dimension affects the welding efficiency of the workpiece, the apparent degree of the back welding seam trace, and the continuity of a welding seam. By judging the actual laser incident angle by the penetration dimension, the welding trace on the back side of a lap test plate can be improved, the phenomenon of penetration instability caused by a gap between an upper plate and a lower plate or welding deformation is reduced, and the welding efficiency of long test plate laser lap welding is improved, thereby improving the overall welding quality of the workpiece, improving the welding strength of the workpiece, and prolonging the service life of the workpiece. Specifically, the first preset range will be changed according to the material of the workpiece, the thickness of the workpiece, and the length value. A smaller penetration dimension is preferred on the premise of satisfying the welding seam joint strength of the workpiece.

During the simulated welding, the preset range includes a first preset range and a second preset range, and when a plurality of penetration dimensions corresponding to a plurality of incident angles fall within the first preset range, S300 also includes the sub-steps as follows.

In S302, multiple incident angles meeting the first preset range are determined according to the first preset range.

In S303, a plurality of melt width dimensions corresponding to the multiple incident angles meeting the first preset range are acquired according to the multiple incident angles meeting the first preset range.

In S304, when a melt width dimension of the plurality of melt width dimensions corresponding to the multiple incident angles meeting the first preset range meets the second preset range, an incident angle corresponding to the melt width dimension is determined as the actual laser incident angle.

In the present embodiment, the first preset range is used for determining the penetration dimension, and the second preset range is used for determining the melt width dimension. When there are multiple penetration dimensions that meet the first preset range, there are multiple corresponding incident angles. In this case, after the first preset range is met, the melt width dimension may be determined by the second preset range. The actual laser incident angle of the workpiece is determined by the melt width dimension. Herein, in the present embodiment, the melt width dimension is a melt width dimension at the lap joint of two workpieces.

Specifically, after the welding simulations are performed on the workpiece at different incident angles, the penetration dimension meeting the first preset range is selected according to the first preset range, and the incident angle corresponding to the penetration dimension is determined. If multiple incident angles satisfy the condition in this case, the melt width dimensions corresponding to the multiple incident angles are compared with the second preset range, and finally the actual laser incident angle is determined according to the incident angle corresponding to the melt width dimension meeting the second preset range. In the present embodiment, the melt width dimension is added as a basis for judgment because the melt width dimension determines the welding strength of the workpiece. Therefore, by judging the actual laser incident angle by the melt width dimension, the welding strength of workpiece welding can be improved. Specifically, after the first preset range is satisfied, when the melt width dimensions are selected, a larger melt width dimension is preferred. Therefore, the melt width dimensions after satisfying the first preset range can be compared, and the incident angle corresponding to the maximum melt width dimension is taken as the actual laser incident angle of the workpiece.

In the present embodiment, after S300 is performed, the process method further includes the step as follows.

In S400, the workpiece is actually welded according to the actual laser incident angle.

By means of the embodiment of the present disclosure, before the workpiece is actually welded, an actual laser incident angle of the workpiece is determined by a simulation technology, and then the workpiece is welded by the actual laser incident angle. Compared with the conventional art in which a vertical incident angle is used to weld a workpiece, the method changes the laser incident angle to make it convenient for protective gas to disperse a plasma cloud generated by high-power welding, thereby improving the power density of a welded surface. Through the process method provided in the present embodiment, the melt width dimension can be increased, and the penetration dimension can be reduced. Thus, the welding strength can be improved, the welding trace on the back side of a welding workpiece is improved, the phenomenon of penetration instability caused by a gap between an upper plate and lower plate or welding deformation is reduced, and the welding efficiency of long test plate laser lap welding is improved.

For ease of understanding of the present disclosure, the present disclosure provides the following embodiments for explanation.

### First Embodiment

FIG. 2 illustrates a structural schematic diagram of workpiece welding. a indicates the penetration dimension of a welding seam, and b indicates a melt width dimension of a welding seam.

In the present embodiment, a workpiece is actually welded according to a preset incident angle, and an actual welding seam parameter of the workpiece is acquired. When the workpiece is simulated, simulated welding is performed on the workpiece first through a preset incident angle, and a second welding seam parameter corresponding to the preset incident angle is acquired. The actual welding seam parameter is compared with the second welding seam parameter. Specifically, the penetration dimensions, the melt width dimensions, the welding seam shapes and the like of the two parameters may be compared, so that the second welding seam parameter is similar to or equal to the actual welding seam parameter, that is, a heat source model parameter for welding seam simulations may be determined.

In the present embodiment, the workpiece is simulated with a laser power of 2 KW and at a welding speed of 2.8 m/min. Welding simulations are performed on the workpiece at different incident angles according to the heat source model parameter, and first welding seam parameters corresponding to the different incident angles are acquired.

Specifically, in the present embodiment, the thicknesses of two workpieces are 0.8 mm and 2 mm, respectively, and the welding simulations are performed under the conditions of incident angles of 0° and 25°, respectively. The simulations show that the melt width dimension is 1018 μm, and the penetration dimension is 400 μm corresponding to the incident angle of 0°; and the melt width dimension is 1028 μm, and the penetration dimension is 364 μm corresponding to the incident angle of 25°. It has been found through simulations that the melt width dimension and the penetration dimension at the incident angle of 25° meet the requirements. Therefore, when the workpiece is welded, the incident angle of 25° is taken as an actual laser welding angle.

When the workpiece is actually welded, the melt width dimension is 1025 μm, and the penetration dimension is 427 μm corresponding to the incident angle of 0°; and the melt width dimension is 1200 μm, and the penetration dimension is 240 μm corresponding to the incident angle of 25°. Through the above data comparison, it is found that the melt width dimension and the penetration dimension corresponding to the laser incident angle obtained during the simulation during actual operation are more in line with the requirements as compared to data of other angles, and the reliability of the data during the simulation is also proved by the above data.

### Second Embodiment

In the present embodiment, a workpiece is actually welded according to a preset incident angle, and an actual welding seam parameter of the workpiece is acquired. When the workpiece is simulated, simulated welding is performed on the workpiece first through a preset incident angle, and a second welding seam parameter corresponding to the preset incident angle is acquired. The actual welding seam parameter is compared with the second welding seam parameter. Specifically, the penetration dimensions, the melt width dimensions, the welding seam shapes and the like of the two parameters may be compared, so that the second welding seam parameter is similar to or equal to the actual welding seam parameter, that is, a heat source model parameters for welding seam simulations may be determined.

In the present embodiment, the workpiece is simulated with a laser power of 3.5 kW and at a welding speed of 3.7 m/min. Welding simulations are performed on the workpiece at different incident angles according to the heat source model parameter, and first welding seam parameters corresponding to the different incident angles are acquired.

Specifically, in the present embodiment, the thicknesses of two workpieces are 2 mm and 2 mm, respectively, and the welding simulations are performed under the conditions of incident angles of 0° and 25°, respectively. The simulations show that the melt width dimension is 1048 μm, and the penetration dimension is 666 μm corresponding to the incident angle of 0°; and the melt width dimension is 1108 μm, and the penetration dimension is 333 μm corresponding to the incident angle of 25°. It has been found through simulations that the melt width dimension and the penetration dimension at the incident angle of 25° meet the requirements. Therefore, when the workpiece is welded, the incident angle of 25° is taken as an actual laser welding angle.

When the workpiece is actually welded, the melt width dimension is 997 μm, and the penetration dimension is 636 μm corresponding to the incident angle of 0°; and the melt width dimension is 1111 μm, and the penetration dimension is 303 μm corresponding to the incident angle of 25°. Through the above data comparison, it is found that the melt width dimension and the penetration dimension corresponding to the laser incident angle obtained during the simulation during actual operation are more in line with the requirements as compared to data of other angles, and the reliability of the data during the simulation is also proved by the above data.

The above is only the preferred embodiments of the present disclosure, not intended to limit the present disclosure. As will occur to those skilled in the art, the present disclosure is susceptible to various modifications and changes. Any modifications, equivalent replacements, improvements and the like made within the spirit and principle of the present disclosure shall fall within the scope of protection of the present disclosure.

What is claimed is:

1. A process method for improving a welding seam quality of laser lap welding, comprising:
S100: performing a laser welding simulation on a workpiece and determining a heat source model parameter of the laser welding simulation;
S200: performing, according to the heat source model parameter, welding simulations on the workpiece at different incident angles, so as to acquire first welding seam parameters corresponding to the different incident angles; and
S300: when at least one first welding seam parameter of the first welding seam parameters falls within a preset range, determining a respective incident angle corresponding to the at least one first welding seam parameter as an actual laser incident angle.

2. The process method for improving the welding seam quality of laser lap welding as claimed in claim 1, wherein S100 comprises:
S101: actually welding the workpiece according to a preset incident angle and acquiring an actual welding seam parameter of the workpiece; and
S103: adjusting the heat source model parameter of the laser welding simulation according to the actual welding seam parameter of the workpiece.

3. The process method for improving the welding seam quality of laser lap welding as claimed in claim 2, wherein before S103 is performed, S100 further comprises:
S102: performing a welding simulation on the workpiece according to the preset incident angle, so as to acquire a second welding seam parameter corresponding to the preset incident angle,
wherein after S102 is performed, S103 comprises: adjusting the heat source model parameter of the laser welding simulation according to the actual welding seam parameter of the workpiece and the second welding seam parameter.

4. The process method for improving the welding seam quality of laser lap welding as claimed in claim 1, wherein a first welding seam parameter comprises a penetration dimension of a welding seam and a melt width dimension of a welding seam.

5. The process method for improving the welding seam quality of laser lap welding as claimed in claim 4, wherein the preset range comprises a first preset range, and S300 comprises:
S301: when at least one penetration dimension falls within the first preset range, determining a respective incident angle corresponding to the at least one penetration dimension as the actual laser incident angle.

6. The process method for improving the welding seam quality of laser lap welding as claimed in claim 4, wherein the preset range comprises a first preset range and a second preset range, and when a plurality of penetration dimensions corresponding to a plurality of incident angles fall within the first preset range, S300 further comprises:
S302: determining the plurality of incident angles meeting the first preset range according to the first preset range;
S303: acquiring a plurality of melt width dimensions corresponding to the plurality of incident angles meeting the first preset range according to the plurality of incident angles meeting the first preset range; and
S304: when a melt width dimension of the plurality of melt width dimensions corresponding to the plurality of incident angles meeting the first preset range meets the second preset range, determining an incident angle corresponding to the melt width dimension as the actual laser incident angle.

7. The process method for improving the welding seam quality of laser lap welding as claimed in claim 1, wherein the heat source model parameter comprises a heat source power, a welding speed, and a heat source radius.

8. The process method for improving the welding seam quality of laser lap welding as claimed in claim 1, wherein after S300 is performed, the process method further comprises:
S400: actually welding the workpiece according to the actual laser incident angle.
